(19) United States
(12) Patent Application Publication
(10) Pub. No.: US 2011/0281388 A1
(43) Pub. Date: Nov. 17, 2011

(54) Cross-Linked Quantum Dots and Methods for Producing and Using the Same

(75) Inventors: Neil Gough, Kingston Upon Hull (GB); Arrelaine A. Dameron, Boulder, CO (US); Ethan Tsai, Boulder, CO (US)

(73) Assignee: HCF PARTNERS, LP, Houston, TX (US)

(21) Appl. No.: 13/129,304

(22) PCT Filed: Nov. 13, 2008
(86) PCT No.: PCT/US2008/083326

§ 371 Date: Jul. 29, 2011

(51) Int. Cl. H01L 51/56; C09K 19/52; B32B 9/04; G02F 1/13; C07F 7/02; B82Y 30/00

(52) U.S. Cl. 438/47; 349/187; 546/14; 428/1.1; 428/447; 257/E51.018; 977/774

(57) ABSTRACT

The present invention relates to modified quantum dots (QDs) and methods for using and producing the same. Some aspects of the invention provide cross-linked quantum dots and methods for producing and using the same.

### FIELD OF THE INVENTION

The present invention relates to modified quantum dots (QDs) and methods for using and producing the same.

### BACKGROUND OF THE INVENTION

QDs are unique semi-conductor nano-crystals that possess several useful properties such as photoluminescence (PL). Photoluminescence refers to absorption of light by a QD at one wavelength and emission of light at a second wavelength. Usually, the absorbed wavelength is shorter than the emitted wavelength such a property is called ‘down converting’. The PL properties of QDs have been used by researchers in the areas of biological studies in a process known as “tagging” where a QD is attached to a specific protein or DNA. Because of down converting property, QDs have also been used as phosphors in light emitting diodes (LEDs), where a composite of red and green emitting QDs is illuminated by the blue (e.g., 445 nm) light. Absorption of blue light and emission of red and green light by the respective QDs combined with the blue light from the LED affords a three component spectrum (white light). This new form of white-emitting LED has been used as a backlight in liquid crystal displays (LCDs). Since the LED is capable of being switched on and off at a much higher rate than cold cathode fluorescent light, this method of generating white light results in a significant power saving in various electronic applications, such as laptop computers.

However, this approach is fundamentally flawed, as color filters are needed to cancel the ‘unwanted’ portion of the white light, to produce a desired color. Such a process of generating white light and re-filtering to produce a desired color significantly reduces the overall efficiency of the system. In a typical LCD, the cell thickness is optimized around the green portion of the spectrum of green, which reduces the efficiency of the LCD in the red and blue portions of the spectrum. Accordingly, an LCD that uses a single wavelength of light in conjunction with high efficiency color change media (CCM) can provide improved operating characteristics and improved efficiency. The incorporation of high efficiency QDs as the CCM is one such approach to achieving improved performance. Unfortunately, conventional QDs are prone to perturbation during secondary processing because they are discreet crystals and are therefore unsuitable for this application. This apparent weakness is brought about by the need for an alignment layer that is deposited on top of the CCM in order to orientate the liquid crystal mixture at the surface. This alignment layer is usually deposited using a solution process, which may result in the removal of the previously deposited QDs. Thus, it is believed that a film formed from suitably cross-linked QDs would prevent perturbation during secondary solution processing and would provide an improved LCD.

Another interesting physical property of QDs is that they exhibit electroluminescence. Such a property is advantageously utilized by incorporating a layer of QDs into an organic light emitting diode (OLED) as the emissive layer. The emissive QD layer is normally formed by depositing the QDs using a solution deposition process onto a hole-transport layer (HTL) with the subsequent layers, such as the hole-blocking (HBL) and electron-transport layer (ETL) are deposited using an organic vapor deposition (OVD) process. Such OLED devices have been shown to possess excellent color purity. However, OVD processes have limited potential in terms of commercial expansion, as this approach to OLED production provides yields of 25% or less and results in very low material utilization rates.

Accordingly there is a need for a method to prevent QD perturbation during secondary solution processing and which is capable of producing OLED devices efficiently in high volume and at reduced cost.

### SUMMARY OF THE INVENTION

The present invention provides modified quantum dots and methods for producing and using the same. Some aspects of the invention provide compositions comprising a cross-linked quantum dots (QDs). Such modified QDs can be used in a wide variety of applications including, but not limited to, as down converters in the form of a color change media (CCM) in liquid crystal displays (LCDs) and as the light emitting component in an organic light emitting diode (OLED) display. Accordingly, in some embodiments, such compositions are adapted for use as a CCM in an LCD or as an emissive layer in an OLED, said composition comprising cross-linked QDs. In other embodiments, the cross-linked QDs comprise two or more different QD compounds. Still in other embodiments, the composition is in the form of a thin film. Within such embodiments, in some instances the thin film comprises a plurality of layers of cross-linked QDs. Yet in other embodiments, the cross-linked QDs comprise green light emitting QDs, red light emitting QDs, or a combination thereof. When the cross-linked QDs comprise two or more different light emitting QDs, each of light emitting QDs are typically configured into distinct regions.

Other aspects of the invention provide a color changing medium (CCM) in a liquid crystal display (LCD) comprising a composition described herein. In some embodiments, the CCM comprises QDs in a discreet color region or pixel. In other embodiments, the CCM comprises a white light emitting region.

Still other aspects of the invention provide an emissive layer of an organic light emitting diode (OLED) comprising a composition described herein. In some embodiments, the emissive layer comprises QDs a discreet color region or pixel. Still in other embodiments, the emissive layer comprises a white light emitting region. Yet in other embodiments, the emissive layer comprises green light emitting QD region, red light emitting QD region, a blue light emitting region, or a combination thereof. In other embodiments, the emissive layer is a photo-active layer. Still in other embodiments, the emissive layer is an electro-active layer.

Yet other aspects of the invention provide methods for producing a cross-linked quantum dots. Such methods typically comprise:
contacting quantum dots comprising a reactive functional group with a surface ligand compound comprising a complementary reactive functional group and a cross-linkable functional group under conditions sufficient to produce modified quantum dots comprising a surface bound ligand moiety which comprises a cross-linkable functional group; and
cross-linking the modified quantum dots to produce cross-linked quantum dots by subjecting the modified quantum dots to conditions sufficient to form cross-linkage between the surface bound ligand moieties.

In some embodiments, the cross-linkable functional group comprises a diene, siloxane, acylate, styrene, epoxide, trifluorovinyloxy or oxetane moiety.

Yet in other embodiments, the step of cross-linking the modified quantum dots comprises thermal annealing, photolysis, reacting the surface bound ligand moiety with a cross-linking compound, or a combination thereof. It should be appreciated that such processes require the presence of appropriate functional group(s). In some instances, the cross-linking compound comprises a complementary functional group. Suitable complementary functional groups include hydroxyl group, a diol, an amine, a carboxylic acid or a thiol moitiey, or a combination thereof. Suitable complementary functional groups for a given functional group are well known to one skilled in the art. See, for example, Harrison and Harrison et al., Compendium of Synthetic Organic Methods, Vols. 1-8 (John Wiley and Sons, 1971-1996), which are incorporated herein by reference in their entirety.

Still yet other aspects of the invention provide a process for producing liquid crystal display (LCD) comprising a color change medium. Typical processes for producing LCD are well known to one skilled in the art. Furthermore, each component of various LCDs are also known to one skilled in the art. In contrast to conventional processes, processes of the invention comprise forming a thin film of color change medium (CCM) layer on a solid LCD substrate, where the thin film of CCM comprises a cross-linked quantum dots (QDs) film. Use of cross-linked QDs as a CCM prevents perturbation of QDs during subsequent solution processes and provides a significant improvement in LCD performance. Processes of the invention can also include forming an alignment layer on top of the CCM layer, similar to current conventional processes. Often the alignment layer is formed using a solution process. That is, a solution of alignment material is placed on top of the CCM layer and processed, e.g., by centrifugation, printing or thermal evaporation, to produce the alignment layer. By using the cross-linked quantum dots, processes of the invention avoid or at least substantially reduce any perturbation of the QDs. After forming the alignment layers, a liquid crystal layer can be produced on top of the alignment layer using any of the conventional methods known to one skilled in the art.

Another aspect of the invention provides processes for producing an organic light emitting diode (OLED). Such processes typically include forming an emissive layer on top of a hole-transport layer, where the emissive layer comprises a thin film of cross-linked quantum dots (QDs). Various methods and components of producing OLEDs are well known to one skilled in the art. See, for example, commonly assigned PCT Patent Application No. PCT/US08/79898, filed on Oct. 15, 2008, which is incorporated herein by reference in its entirety. Processes of the invention can also include forming a hole-blocking layer on top of the emissive layer. Typically, the hole-blocking layer is formed using an organic vapor deposition (OVD) process, which is well known to one skilled in the art. It is believed that by using the cross-linked quantum dots, processes of the invention avoid or at least substantially reduce any perturbation of the QDs during a solution based deposition process, such as spin coating or inkjet printing, thereby significantly increasing the yield of OLEDs.

### BRIEF DESCRIPTION OF THE DRAWINGS

FIG. 1 is a schematic of a red, green and blue (RGB) LCD comprising a monochromatic blue LED and possessing red and green cross-linked QDs as the CCM in the red and green pixels. It should be noted that no CCM is required for the blue pixel. The LC cell gap is tuned to the discreet wavelength of the LED used as the light source (e.g., emitting light between 440 and 470 nm).

FIG. 2 is a schematic of a red, green, blue and white (RGBW) LCD comprising a monochromatic blue LED and possessing red and green cross-linked QDs as the CCM in the red and green pixels. It should be noted that no CCM is required for the blue pixel. The white pixel is formed by blending the red and green QDs. The LC cell gap is tuned to the discreet wavelength of the LED used as the light source (e.g., emitting light between 440 and 470 nm).

FIG. 3 is the X-ray photoelectron spectrum (XPS) of a cross-linked 3-mercaptopropyltrimethoxysilane-capped-QD film.

FIG. 4 is the spectrum of a cross-linked green emitting QD film irradiated at 465 nm.

FIG. 5 is a white light spectrum of a cross-linked QD film comprising a red layer on top of a green layer of QDs illuminated with an LED emitting 445 nm light.

FIG. 6 shows the electro-optic data for a series of OLED devices comprising both a cross-linked and un-linked QD layer.

FIG. 7 is the electroluminescent spectra of a cross-linked, green emitting QD-OLED device.

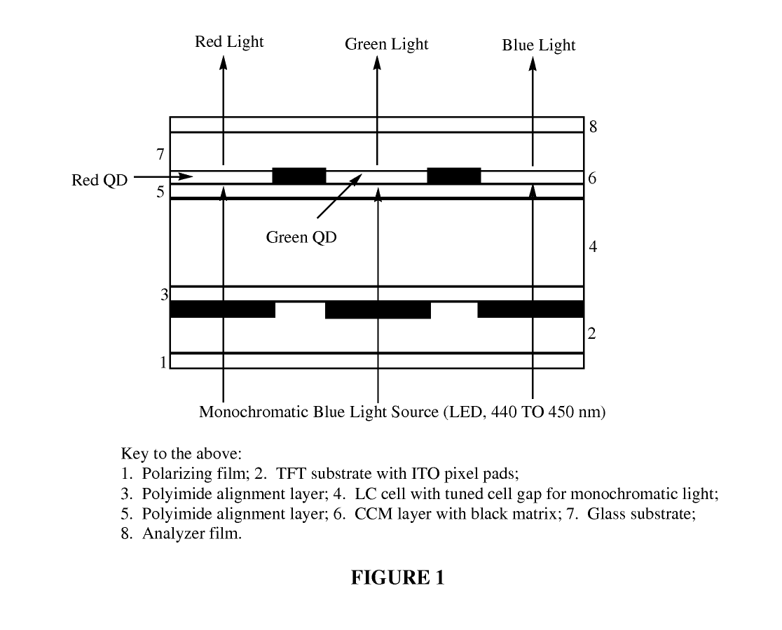

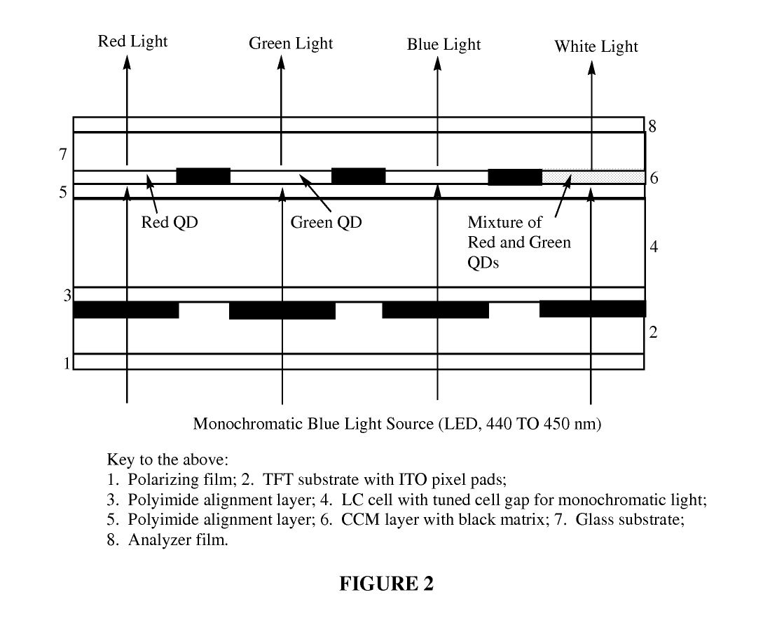

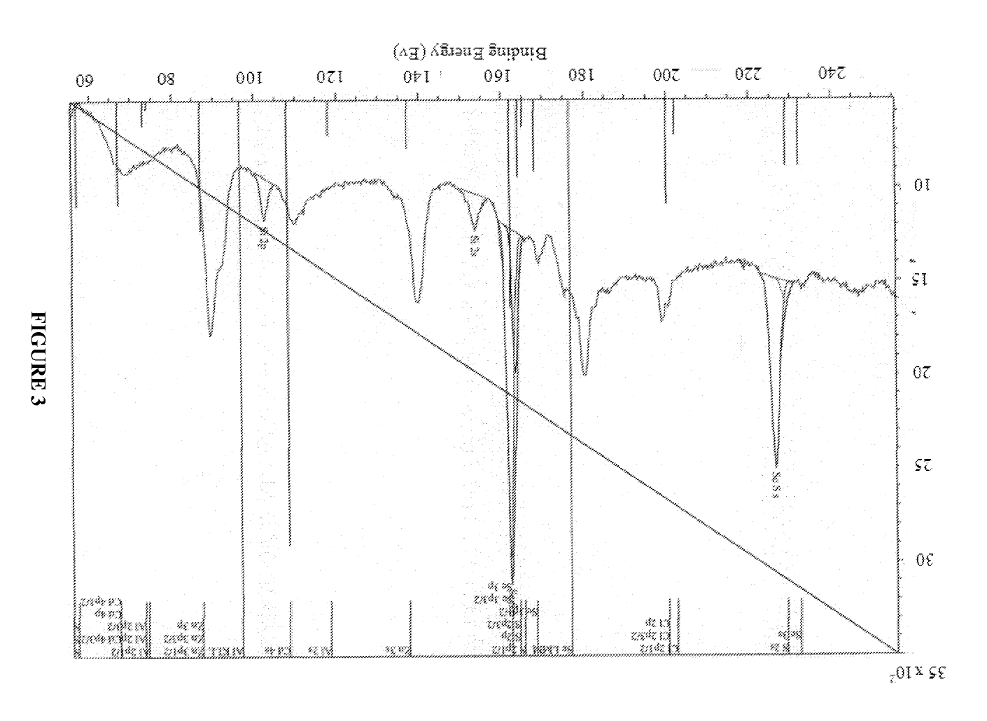

### DETAILED DESCRIPTION OF THE INVENTION

“Alkyl” refers to a saturated linear monovalent hydrocarbon moiety of one to twenty, typically one to twelve and often one to six, carbon atoms or a saturated branched monovalent hydrocarbon moiety of three to twenty, typically three to twelve and often three to six, carbon atoms. Alkyl group can be optionally substituted. When two or more substituents are present in an alkyl group, each substituent is independently selected as long as they do not form an unstable moiety. When an alkyl group is substituted with one or more halide, it can also be referred to as haloalkyl. Exemplary alkyl group include, but are not limited to, methyl, ethyl, n-propyl, 2-propyl, tert-butyl, pentyl, and the like.

“Alkylene” refers to a saturated linear saturated divalent hydrocarbon moiety of one to twenty, typically two to twelve and often two to six, carbon atoms or a branched saturated divalent hydrocarbon moiety of three to twenty, typically three to twelve, carbon atoms. Exemplary alkylene groups include, but are not limited to, methylene, ethylene, propylene, butylene, pentylene, and the like.

“Aryl” refers to a monovalent mono-, bi- or tricyclic aromatic hydrocarbon moiety of 6 to 15 ring atoms which is optionally substituted with one or more, typically one, two, or three substituents within the ring structure. When two or more substituents are present in an aryl group, each substituent is independently selected.

“Aralkyl” refers to a moiety of the formula —R^{b}R^{c} where R^{b} is an alkylene group and R^{c} is an aryl group as defined herein. Exemplary aralkyl groups include, but are not limited to, benzyl, phenylethyl, 3-(3-chlorophenyl)-2-methylpentyl, and the like.

“Cycloalkyl” refers to a non-aromatic, monovalent mono- or bicyclic hydrocarbon moiety of three to ten ring carbons. The cycloalkyl can be optionally substituted with one or more, typically one, two, or three, substituents within the ring structure. When two or more substituents are present in a cycloalkyl group, each substituent is independently selected.

“Cycloalkylalkyl” refers to a moiety of the formula —R^{d}R^{e} where R^{d} is an alkylene group and R^{e} is a cycloalkyl group as defined herein. Exemplary cycloalkylalkyl groups include, but are not limited to, cyclopropylmethyl, cyclohexylpropyl, 3-cyclohexyl-2-methylpropyl, and the like.

The terms “halo,” “halogen” and “halide” are used interchangeably herein and refer to fluoro, chloro, bromo, or iodo.

“Haloalkyl” refers to an alkyl group as defined herein in which one or more hydrogen atom is replaced by same or different halo atoms. The term “haloalkyl” also includes perhalogenated alkyl groups in which all alkyl hydrogen atoms are replaced by halogen atoms. Exemplary haloalkyl groups include, but are not limited to, —CH₂Cl, —CF₃, —CH₂CF₃, —CH₂CCl₃, and the like.

The term “functional group” in organic chemistry is well recognized by one skilled in the art. An exemplary understanding of the term “functional group” includes referring to one or a group of atoms within a molecule that is responsible for the characteristic chemical reactions of that molecule. The same functional group will generally undergo the same or similar chemical reaction(s). However, its relative reactivity can be modified by nearby functional groups. It should be appreciated that the term “functional group” is used herein to mean the broadest definition known to one skilled in the art of organic chemistry.

“Complementary functional group” is well known to one skilled in the art of organic chemistry. Typically, such a term refers to a functional group that is capable of reacting with a given functional group to form a chemical bond.

When describing a chemical reaction, the terms “treating”, “contacting” and “reacting” are used interchangeably herein, and refer to adding or mixing two or more reagents under appropriate conditions to produce the indicated and/or the desired product. It should be appreciated that the reaction which produces the indicated and/or the desired product may not necessarily result directly from the combination of two reagents which were initially added, i.e., there may be one or more intermediates which are produced in the mixture which ultimately leads to the formation of the indicated and/or the desired product.

Full color LCDs are broad sectrum emitters meaning that they use backlights that emit white light and color filters that act as band pass filters. Color filters allow light to be transmitted in only a relatively narrow region of the spectrum and block the remainder of light from being transmitted. Such a method is a highly inefficient usage of light. By replacing both the standard white light emitter with a narrow band monochromatic light source and the color filter with a highly efficient CCM, it is possible to achieve a significant reduction in power consumption. In one particular embodiment of the invention, each color pixel is illuminated with blue monochromatic light, typically emitting wavelength in the range 440 to 450 nm. Such a device reduces the amount of required light to achieve a specific brightness by approximately two thirds, which provides for prolonged battery life and reduced cost in manufacture.

In order to achieve this power and cost savings, some embodiments of the invention use a highly efficient CCM. Within these embodiments, in some instances QDs are used as the CCM. Some QDs possess a very high quantum yield; indeed, it is possible to achieve efficiencies of 90% and more. QDs efficiency relates to the number of incident high energy photons absorbed and re-emitted as lower energy photons, that is, effective down conversion. The required QD film thickness is a function of the molar extinction coefficient, which is a measure of how strongly a chemical species absorbs light at a given wavelength. Another advantage of this approach for achieving full color is that only two CCM pixels are required, as the blue component can be used without modification or conversion. However, it should be appreciated that for more advanced systems comprising RGBW, the red and green QDs can be combined in the correct proportions in order to provide white emitting pixels.

Much effort has been placed into the development of OLED devices comprising QDs as the emissive layer. Currently, OLED devices are produced using organic vapor deposition (OVD) methods to deposit the hole-blocking layer (HBL) and electron-transport layer (ETL) on top of the QD emissive layer. This process has been brought about because of the fragility of the QD layer(s), which are highly prone to perturbation when subjected to secondary processing steps that use solution process. As used herein, a “solution process” refers to a process that uses a solution of material to coat the desired layer. Indeed, it is well recognized that an attempt to spin coat a layer onto of a standard QD layer results in the removal of QD layer. Such a short coming has at least to some extent limited the attractiveness of QDs as emissive materials in OLED devices. In contrast, high volume production of OLED devices will more likely be achieved using printable materials. The development of advanced printing techniques affords for high throughput and will possibly reduce the manufacturing costs of organic electronic devices compared to OVD methods, which require numerous mask sets, highly expensive vacuum deposition equipment and which are limited to small substrate sizes.

The present inventors have found that these and other shortcomings of QDs can be overcome by cross-linking the QDs. In particular, it has been found by the present inventors that using cross-linked QDs as an emissive layer renders the emissive layer substantially impervious to subsequent solvent exposure. Such a system can significantly reduce the cost and improve color purity compared to existing emissive materials.

A QD is a nano-particulate semiconductor, whose excitons are confined in all three spatial dimensions. As a consequence of this quantum confinement, QDs possess properties that lie between those of bulk semiconductors and those of discrete molecules. QDs are unique among advanced materials in that their properties can be readily engineered, providing QDs that comprise the same elements, but which, for instance, can be made to emit light at different wavelengths by changing the size or the relative composition of the QD.

Colloidal semiconductor QDs are typically synthesized from precursor compounds dissolved in solution and is often based on a three component system comprising precursors, organic surfactants, and solvents. On heating a reaction medium to the desired temperature, the precursors chemically transform into monomers. Once the monomers reach a high enough super-saturation level, the QD growth commences via a nucleation process. The temperature during the growth process is one of the factors in determining optimal conditions for the QD growth. Generally, the temperature must be sufficiently high to allow for rearrangement and annealing of the atoms during the synthesis process. However, the temperature should not be too high so as to inhibit crystal growth. An additional factor, which also needs to be controlled during the QD growth process, is the monomer concentration. The growth process of QD often occurs in two different regimes, those being ‘focusing’ and ‘defocusing’. At high monomer concentrations, the critical size (the size where QDs neither grow nor shrink) is very narrow, resulting in growth of nearly all particles. In this regime, the relative rates of growth favor the growth of smaller particles, which provides ‘focus’ and provides a high degree of mono-dispersity with respect to particle size. The size focusing is optimal when the monomer concentration is kept such that the average QD size present is always slightly larger than the critical size. When the monomer concentration is depleted during growth, the critical size becomes larger than the average size present, and the distribution “defocuses” as a result of a process known as Ostwald ripening.

There are colloidal methods to produce many different semiconductor binary and ternary QDs. Exemplary QDs produced by colloidal methods include, but are not limited to, cadmium-selenide (CdSe), cadmium-sulfide (CdS), indium-arsenide (InAs), and indium-phosphide (InP) cadmium-tellurium-sulfide (CdTeS). The number of atoms that comprise a QD can range from 100 to 100,000 and the diameter for practical purposes can range from 2 to 20 nm.

Other aspects of the present invention provide methods for incorporating a cross-linkable surface ligand onto the surface of a QD. Such QDs comprising a surface bound ligand can be used to produce a thin cross-linked film of QDs. These thin films can be used as a color change medium for LCD applications as an emissive layer in an OLED device. The surface bound ligands can comprise a functional group, such as diene or siloxane, that readily reacts with a secondary cross-linking molecule, such as a diol, amine, or carboxylic acid. QDs comprising surface bound ligands are soluble in common solvents and can be formed into a film by typical methods such as spin coating or printing.

A reproducible and uniform film comprising QDs of the present invention (e.g., QDs comprising a surface bound ligand) can be cross-linked by thermal annealing, photolysis (e.g., exposure to light), or addition of another component. The cross-linking yields a film that is substantially uniform and reproducible, but resistant to the various solvents, such as solvents used to fabricate the film as well as other common solvents used to fabricate the additional layers of LCDs and OLEDs. Incorporation of such a system allows for the repeated deposition of the same type of material (QD multi-layers) without the risk of destroying any previously formed layers, as well as being resistant to further processing in general. Further, this approach expands the solvent choices available at each step during device fabrication by allowing the same solvent to be used after the annealing step.

An example of a useful surface ligand compound for QDs that is capable of being cross-linked include a compound of the formula A-R—B, where A and B are independently a hydrogen, alkyl, or a functional group such as thiol, siloxane, hydroxyl, alkoxy, diene, provided at least one of A or B is a functional group, and R is an alkylene, arylene, cycloalkylene, aralkylene, or cycloalkylalkylene. In some embodiments a useful surface ligand compound is thiosiloxane of the formula: (R′O)₃Si—R—SH, where each R′ is independently H or alkyl, and R is an alkylene, arylene, cycloalkylene, aralkylene, or cycloalkylalkylene. One particular example of thiosiloxane surface ligand compound is:

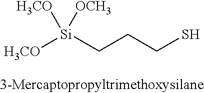

Other examples of useful compounds capable of participating in the cross-linking process as well as being useful as a linker compound between two surface bound ligands include various alkyl, aryl, aralkyl, cycloalkyl, aralkyl, cycloalkylalkyl groups comprising a halide, siloxane, olefin, hydroxy, alkoxy, amine, or a combination thereof. Particular examples of such compounds include:

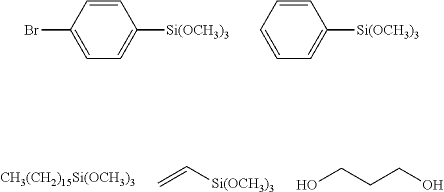

Additional objects, advantages, and novel features of this invention will become apparent to those skilled in the art upon examination of the following examples thereof, which are not intended to be limiting. In the Examples, procedures that are constructively reduced to practice are described in the present tense, and procedures that have been carried out in the laboratory are set forth in the past tense.

### Examples

Pyridine capped QDs (any suitable QD, such as those described in US2007/0111324 may be used) and 3-mercaptopropyltrimethoxysilane (>1:100000 molar ratio) were dissolved chloroform (CHCl₃) and the solution sonicated for ca. 2 h (the longer the sonication the more complete the exchange) at room temperature. The QDs were precipitated out of the solution via the addition of anhydrous acetonitrile and centrifugation. The QDs were rinsed with acetone and sonicated briefly (<5 mins) in order to remove excess 3-mercaptopropyltrimethoxsilane. This suspension was centrifuged in order to precipitate the QDs (3 times) and the slurry obtained placed in a vacuum chamber until all visible traces of the acetone were removed, but not until the QDs were completely dried (<30 mins in vacuum). The QDs were re-suspended in CHCl₃ to yield the appropriate concentration for film processing.

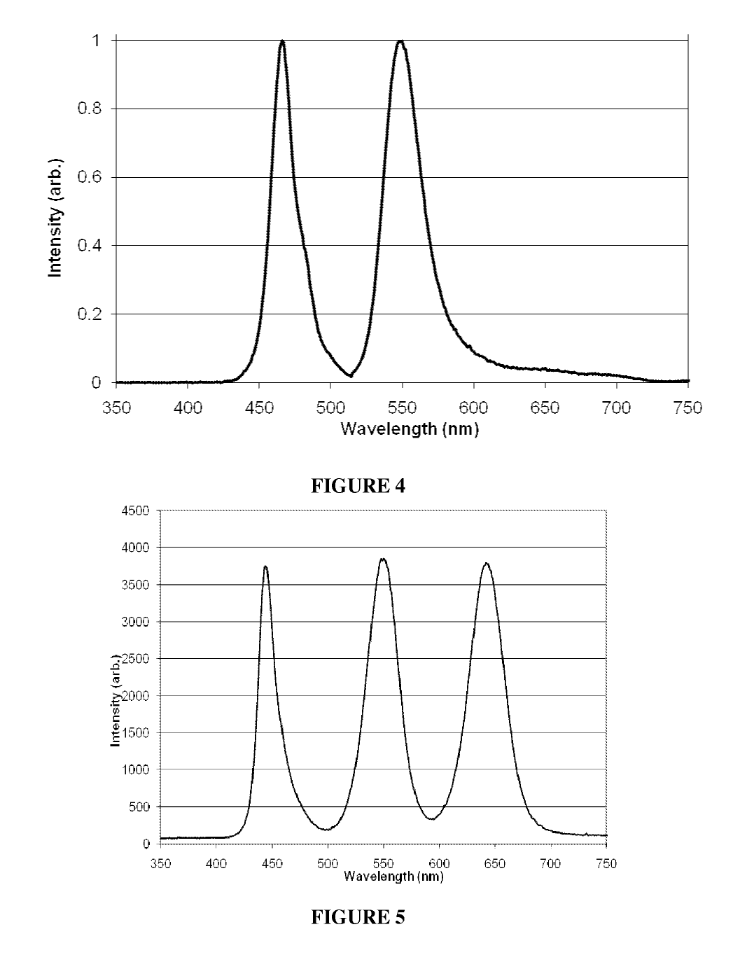

A solution of 3-mercaptopropyltrimethoxysilane capped green emitting QDs (3 mg cm⁻³) were cast onto a glass substrate and the substrate spun at 3000 rpm for 30 s. The resulting film was cross-linked by annealing the films at 125° C. for ca. 10 min (FIG. 3 shows XPS spectra for a cross-linked 3-mercaptopropyltrimethoxysilane capped QD film). The spectra shows only Cd, Se, Zn, S, Si, C, and O atoms present in the films. Once cured, the film was exposed to 465 nm light and the spectra recorded (FIG. 4). The film was then washed with CHCl₃, with no change in the observed spectra. A second film comprising 3-mercaptopropyltrimethoxysilane capped red emitting QDs was then formed on top of the first film using the process described above, with the resulting spectra detailed in FIG. 5.

A multilayer OLED device was fabricated using a combination of solution processing and chemical vapor deposition (CVD). The structure of this stack was indium tin oxide (ITO), PEDOT:PSS (25.00 nm, Baytron P®), poly-N-(4-(9H-carbazol-9-yl)phenyl)methacrylamide: poly(methyl methacrylate) (PCPMAAM:PMMA) (35.00 nm), QD layer, 2,2′,2″-(1,3,5-benzinetriyl)-tris(1-phenyl-1-H-benzimidazole) (TPBi) (40.00 nm), LiF (1.50 nm) and a cathode comprising Al.

ITO-coated glass was cleaned thoroughly by sonication in a 2% Tergitol solution, followed by a rinsing in de-ionized water and immersion for 10 minutes in a 5:1:1 solution of DI water:ammonium hydroxide:hydrogen peroxide heated to 70° C. Substrates were then rinsed with DI water and sonicated in acetone and methanol for 15 minutes each. After drying with nitrogen, they were cleaned with UV/ozone to remove any remaining organic contaminants. Spin-coating of PEDOT:PSS, the PCPMAAM:PMMA and QD layers was performed in a nitrogen-filled glove box. A stock solution of Baytron P® diluted in methanol (0.3 mL, 3:5) was cast onto the ITO substrate. After the solution had completely wet the surface, the substrate was accelerated to 3000 rpm for 1 second, then to 6000 rpm and held at that rate for 30 seconds. The film was annealed on a hotplate inside the glove box at 125° C. for 10 minutes. After annealing, the substrate was placed on the spin-coater, and a solution of PCPMAAM:PMMA (12.8 mg/mL) in toluene: N-methyl-2-pyrrolidone (NMP) (5:1) was dropped onto the surface. The substrate was accelerated to 3000 rpm and held at this rate for 60 seconds and the film annealed at 125° C. for 30 min under an inert atmosphere. A solution of the 3-mercaptopropyltrimethoxysilane capped green emitting QDs (3.0 mg/mL) in CHCl₃ was cast onto the surface of the substrate. The substrate was spun at 3000 rpm for one minute and half the substrates placed on a hot plate at 150° C. for 20 min under an inert atmosphere. The substrate with the PEDOT:PSS/PCPMAAM:PMMA/QD tri-layer was moved in an inert atmosphere to a vacuum chamber. A 40.00 nm thick layer of TPBi deposited at a rate of ˜5.0 Ås⁻¹. Film deposition was carried out at a base pressure of 2×10⁻⁶ mbar. The chamber was vented and the substrates shadow-masked for depositing patterned cathodes was placed over the devices. The devices were placed back into the chamber and pumped to a base pressure of 2×10⁻⁶ mbar. A bi-layer of lithium fluoride and aluminum was deposited using thermal evaporation at a rate of 0.1 Ås⁻¹ for LiF and 5-25 Ås⁻¹ for Al. Finished devices were removed from the chamber and characterized under an inert atmosphere.

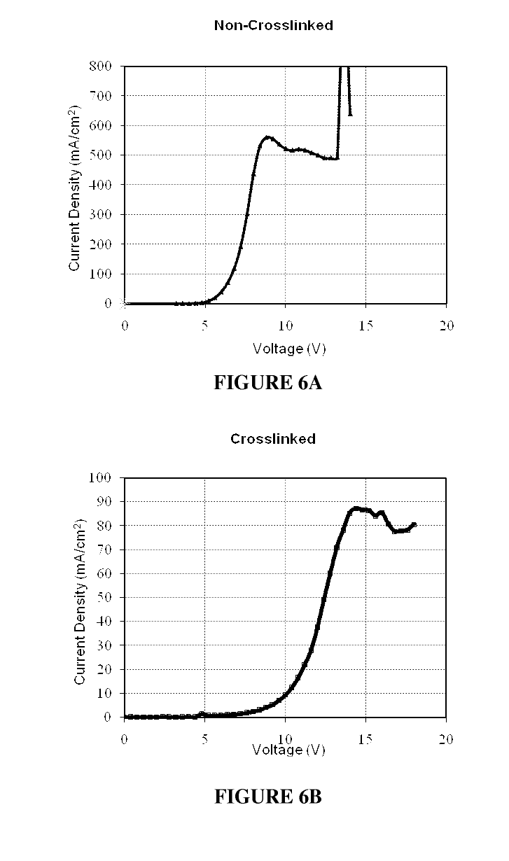

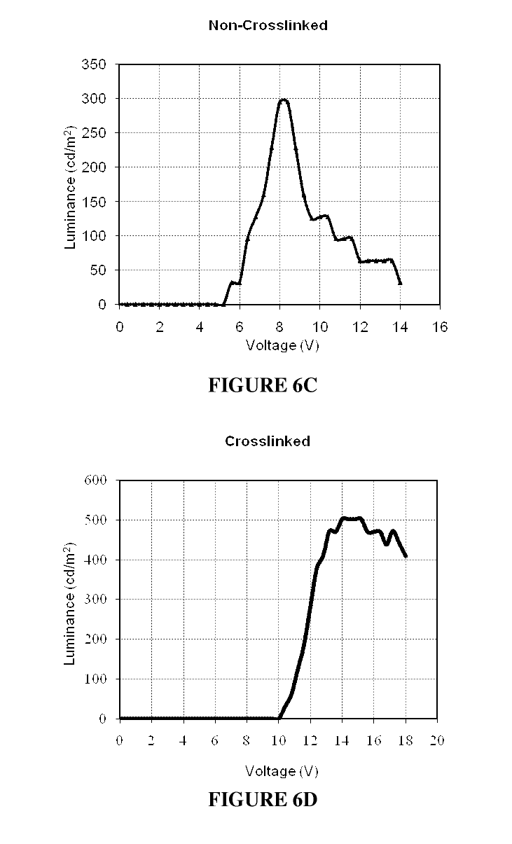

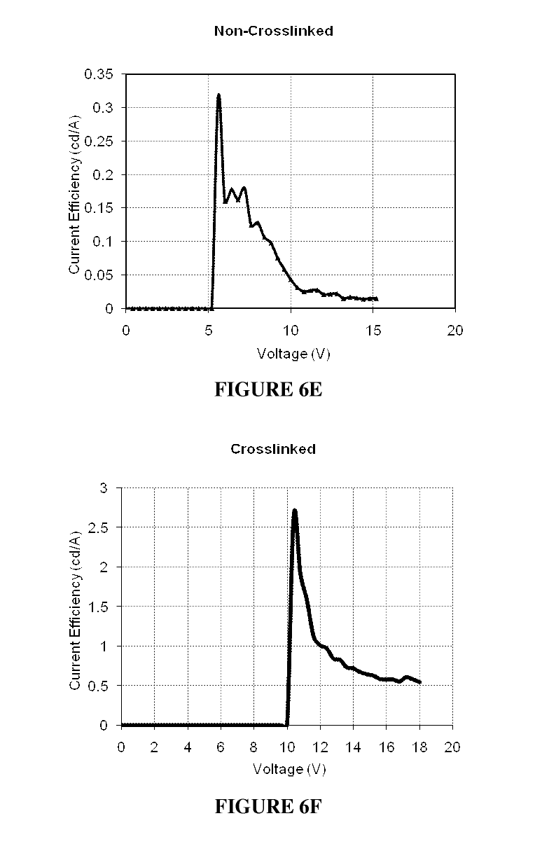

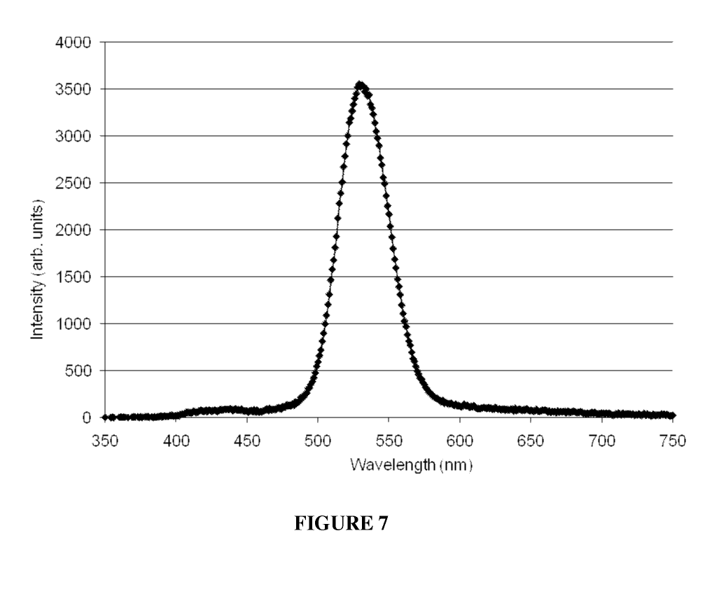

FIGS. 6 and 7 provide some physical characteristics of the devices described above.

The foregoing discussion of the invention has been presented for purposes of illustration and description. The foregoing is not intended to limit the invention to the form or forms disclosed herein. Although the description of the invention has included description of one or more embodiments and certain variations and modifications, other variations and modifications are within the scope of the invention, e.g., as may be within the skill and knowledge of those in the art, after understanding the present disclosure. It is intended to obtain rights which include alternative embodiments to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

What is claimed:

1. A composition adapted for use as a color changing medium in a liquid crystal display (LCD) or as an emissive layer in an organic light emitting diode (OLED), said composition comprising cross-linked quantum dots (QDs).

2. The composition of claim 1, wherein said cross-linked QDs comprises two or more different QD compounds.

3. The composition of claim 1, wherein said composition is in the form of a thin film.

4. The composition of claim 3, wherein said thin film comprises a plurality of layers of cross-linked QDs.

5. The composition of claim 1, wherein said cross-linked QDs comprise green light emitting QDs, red light emitting QDs, or a combination thereof.

6. A color changing medium (CCM) in a liquid crystal display (LCD) comprising a composition of claim 1.

7. The CCM of claim 6, wherein said CCM comprises QDs in a discreet color region or pixel.

8. The CCM of claim 6, wherein said CCM comprises a white light emitting region.

9. An emissive layer of an organic light emitting diode (OLED) comprising a composition of claim 1.

10. The emissive layer of an OLED of claim 9, wherein said emissive layer comprises QDs in a discreet color region or pixel.

11. The emissive layer of an OLED of claim 9, wherein said emissive layer comprises a white light emitting region.

12. The emissive layer of an OLED of claim 9, wherein said emissive layer comprises green light emitting QD region, red light emitting QD region, a blue light emitting region, or a combination thereof.

13. The emissive layer of an OLED of claim 9, wherein said emissive layer is a photo-active layer.

14. The emissive layer of an OLED of claim 9, wherein said emissive layer is an electro-active layer.

15. A method for producing cross-linked quantum dots, said method comprising:
contacting quantum dots comprising a reactive functional group with a surface ligand compound comprising a complementary reactive functional group and a cross-linkable functional group under conditions sufficient to produce modified quantum dots comprising a surface bound ligand moiety which comprises a cross-linkable functional group; and
cross-linking the modified quantum dots to produce cross-linked quantum dots by subjecting the modified quantum dots to conditions sufficient to form cross-linkage between the surface bound ligand moieties.

16. The method of claim 15, wherein the cross-linkable functional group comprises a diene, siloxane, acylate, styrene, epoxide, trifluorovinyloxy or oxetane moiety.

17. The method of claim 15, wherein said step of cross-linking the modified quantum dots comprises thermal annealing, photolysis, reacting the surface bound ligand moiety with a cross-linking compound, or a combination thereof.

18. The method of claim 17, wherein the cross-linking compound comprises a functional group comprising a diol, an amine, a carboxylic acid, thiol, or a combination thereof.

19. A process for producing liquid crystal display (LCD) comprising a color change medium, said process comprising:
forming a thin film of color change medium (CCM) layer on a solid LCD substrate, wherein said thin film of CCM comprises a cross-linked quantum dots (QDs);
forming an alignment layer on top of said CCM layer; and
forming a liquid crystal layer on top of said alignment layer.

20. The process of claim 19, wherein the alignment layer is formed using a solution process.

21. A process for producing an organic light emitting diode (OLED) comprising:
forming an emissive layer on top of a hole-transport layer, wherein the emissive layer comprises a thin film of cross-linked quantum dots (QDs); and
forming a hole-blocking layer on top of the emissive layer.

22. The process of claim 21, wherein the hole-blocking layer is formed using an organic vapor deposition process.
